(19) United States
(12) Patent Application Publication
(10) Pub. No.: US 2006/0088983 A1
(43) Pub. Date: Apr. 27, 2006

(54) Method of dividing wafer

(76) Inventors: Shinichi Fujisawa, Tokyo (JP); Ryou Matsuhashi, Tokyo (JP); Takashi Ono, Tokyo (JP); Toshihiro Funanaka, Tokyo (JP); Jun Hachiya, Tokyo (JP); Akihito Kawai, Tokyo (JP)

Correspondence Address: WENDEROTH, LIND & PONACK, L.L.P., 2033 K STREET N. W., SUITE 800, WASHINGTON, DC, 20006-1021, US

(21) Appl. No.: 11/251,933

(22) Filed: Oct. 18, 2005

(30) Foreign Application Priority Data
Oct. 21, 2004 (JP) 2004-306747

(51) Int. Cl. H01L 21/78; H01L 21/302

(52) U.S. Cl. 438/462; 438/464; 438/710

(57) ABSTRACT

In order to efficiently divide the wafer into individual devices in dicing the wafer without deteriorating the quality of the devices, the front surface of the wafer is coated with a resist film except the regions corresponding to the streets, grooves of a depth corresponding to the finished thickness of the devices are formed by plasma etching in the regions corresponding to the streets, and the back surface of the wafer is ground so that the grooves are exposed from the side of the back surface and that the wafer is divided into individual devices.

### BACKGROUND OF THE INVENTION

1. Field of the Invention

The present invention relates to a method of dividing a wafer.

2. Related Art

A wafer having a plurality of devices formed on the front surface side thereof by being sectionalized by streets, is ground on its back surface to possess a predetermined thickness and is, then, cut and diced along the streets so as to be divided into individual devices and used in various electronic devices (see, for example, JP-A-2004228133).

At the time of dicing, however, the cutting blade rotating at a high speed bites into the street of the wafer whereby the devices are partly cut away due to the crushing force of the cutting blade and, hence, the die strength of the devices constituting the wafer decreases to deteriorate the quality.

At the time of dicing, further, the cutting blade is precisely positioned on each street to cut the streets one by one, which is not efficient. In particular, when the size of the devices is small and there are an increased number of streets to be cut, a considerably long period of time is required for cutting all of the streets, leaving a problem of a very decreased productivity.

### SUMMARY OF THE INVENTION

In order to solve the problem, therefore, an object of the present invention is to make it possible to efficiently divide the wafer into individual devices in dicing the wafer without deteriorating the quality of the devices.

The present invention is concerned with a method of dividing a wafer having a plurality of devices formed in front surface thereof being sectionalized by streets into individual devices, including: a resist film coating step of coating the surface of the wafer with a resist film except the regions corresponding to the streets; a grooves-forming step of plasmatizing a fluorine stabilizing gas and supplying it onto the surface of the wafer to form grooves of a depth equivalent to finishing thickness of the devices in the regions corresponding to said streets; and a grinding step of sticking a protection member onto the front surface side, and grinding back surface of the wafer so that the grooves are exposed from the back surface side. The regions corresponding to the streets may be the whole of the streets or part of the streets.

Between the grooves-forming step and the grinding step, it is desired to carry out a resist film removing step is carried out for removing the resist film from the surface of the wafer. After the grinding step, further, it is desired to carryout a stress-relieving step for removing strain due to the grinding remaining in the back surface of the wafer. As the stable fluoride gas, there can be used, for example, SF₆, CF₄, C₂F₆, C₂F₄ or CHF₃. In the resist film-removing step, it is desired that oxygen is plasmatized and is supplied onto the resist film to turn the resist film into ashes so as to be removed.

According to the present invention, the wafer is divided into individual devices relying upon the plasma etching and grinding instead of cutting by means of a cutting blade. Therefore, chippings cannot cause in the devices, the die strength of the devices does not decrease, and the quality thereof is not deteriorated. Further, the grooves-forming step is capable of forming grooves simultaneously in all streets by plasma etching, which is very efficient improving the productivity. Moreover, the front surface of the wafer is coated with a resist film by using an exposure device and a device for forming a resist film that have been used in a device-forming step of forming the devices on the wafer (pre-step), and the regions corresponding to the streets are exposed. In this state, an post-step is carried out for forming the grooves and for grinding, and accordingly, it is possible to employ, in an ordinary flow, a plasma etching device, a grinding device and a stress-relieving device that have heretofore been used in the post-step. Therefore, it is not necessary to use in the post-step the devices essentially used in the pre-step, and the flow of the steps can be simplified.

Further, the stress-relieving step carried out after the grinding step to remove the strain due to grinding in the back surface of the wafer makes it possible to improve the die strength and to further improve the quality.

### BRIEF DESCRIPTION OF THE DRAWING

FIG. 1 is a sectional view schematically illustrating an example of a series of steps of the present invention;

FIG. 2 is a perspective view illustrating a method of coating the front surface of the wafer with a resist film;

FIG. 3 is a schematic sectional view illustrating a method of removing the resist film from the upper side of the streets;

FIG. 4 is a perspective view illustrating a state where the resist film is removed from the upper side of the streets;

FIG. 5 is a sectional view schematically illustrating the constitution of a plasma etching device;

FIG. 6 is a perspective view of a wafer formed with grooves in the front surface thereof;

FIG. 7 is a perspective view illustrating the wafer formed with grooves in the front surface thereof, and a protection member;

FIG. 8 is a perspective view illustrating a state where the protection member is stuck onto the front surface of the wafer;

FIG. 9 is a perspective view of a grinding device; and

FIG. 10 is a sectional view schematically illustrating a method of relieving stress.

### DETAILED DESCRIPTION OF PREFERRED EMBODIMENT

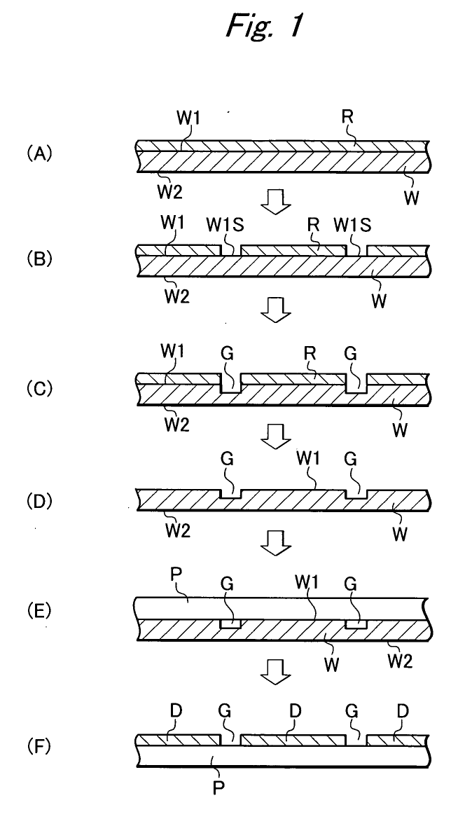

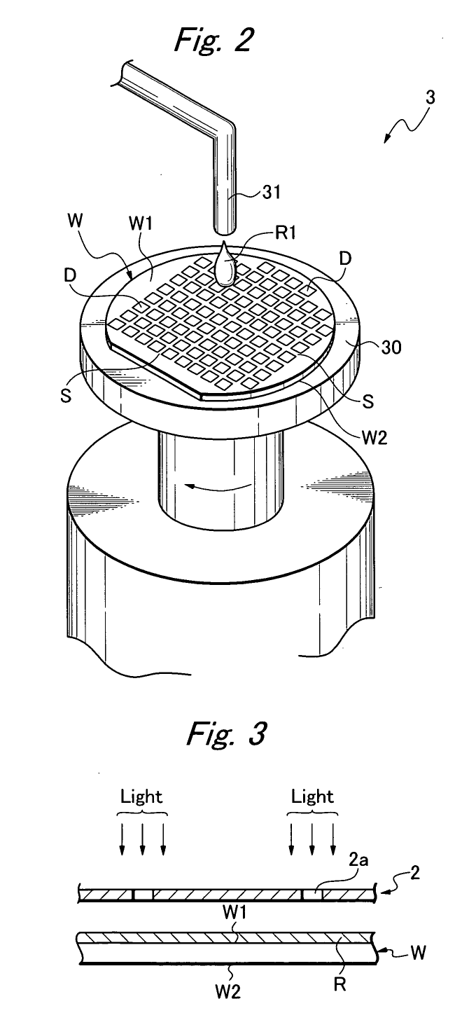

Referring to FIG. 1(A), first, the whole front surface W1 of a wafer W is coated with a resist film R. On the front surface W1 of the wafer W as shown in FIG. 2, there are formed a plurality of devices D being sectionalized by streets S. A spin coater 3 shown in FIG. 2, for example, can be used for coating the whole front surface W1 of the wafer W with the resist film R. In the spin coater 3 of FIG. 2, a back surface W2 of the wafer W is held by a holding table 30. A resist material R1 is dripped from a nozzle 31 while rotating the holding table 30, whereby the whole front surface W1 of the wafer W is coated with the resist film R as shown in FIG. 1(A).

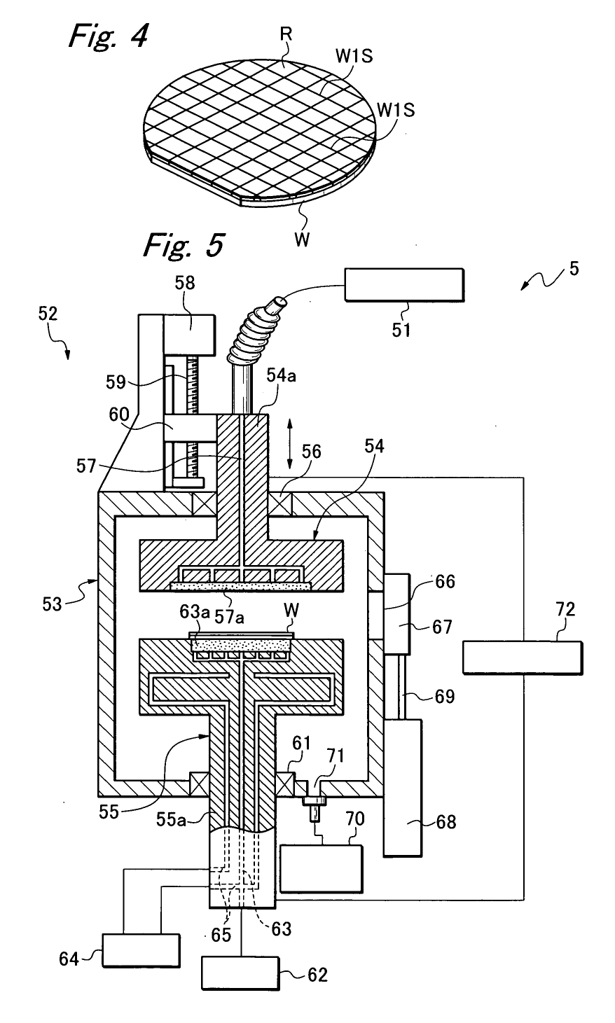

Next, the front surface W1 of the wafer W is picked up the image by using a camera to recognize the streets S. Referring to FIG. 3, the resist film R is irradiated with light such as ultraviolet ray or X-ray via a photomask 2 having a mask pattern 2a formed like the same lattice as the streets S, so that portions of the resist film R corresponding to the streets S in the front surface W1 are exposed to light. Upon developing the portions exposed to light, the resist film is removed at the portions corresponding to the streets S in the front surface W1 and the portions W1S corresponding to the streets are exposed as shown in FIGS. 1(B) and 4 (resist film coating step). Here, it is desired that the width of the mask pattern 2a is narrower than the width of the streets S to prevent the resist film covering the devices D from being exposed to light. That is, the width of the portions W1S corresponding to the streets may be the same as the width of the streets S or may be narrower than the width of the streets S.

Even without using the photomask, the front surface W1 of the wafer W is imaged by using a camera to detect the streets S, and the detected streets S only are irradiated with light so that the portions W1S corresponding to the streets are exposed in the same manner as ones shown in FIGS. 1(B) and 4. Further, after the streets S are detected, the streets S only are physically pushed so that the portions W1S corresponding to the streets are exposed. Furthermore, the resist material may be ejected onto the regions other than the portions corresponding to the streets that are detected, or the portions corresponding to the streets may be coated with a masking material that repels the resist material, followed by the coating with the resist film.

Referring next to FIG. 1(C), in the portions W1S corresponding to the streets, which are the regions corresponding to the streets S, there are formed grooves G having a depth corresponding to the finished thickness of the devices D (grooves-forming step). In the step of forming the grooves, there can be used a plasma etching device 5 shown in FIG. 5, for example.

The plasma etching device 5 includes a gas feeding unit 51 and an etch-treating unit 52. The gas feeding unit 51 is provided with a stable fluoride gas which is a stable gas containing fluorine, such as SF₆, CF₄, C₂F₆, C₂F₄, or CHF₃. On the other hand, in the etch-treating unit 52, a work W ground and to be worked is received therein, and the stable fluoride gas fed from the gas feeding unit 51 is plasmatized to etch the wafer W.

The etch-treating unit 52 contains etching gas feeding means 54 in the upper portion of a chamber 53 in which the plasma etching will be conducted, and contains a chuck table 55 in the lower portion thereof to hold a plate to be etched.

The etching gas feeding means 54 has a function for feeding an etching gas onto the exposed surface of the wafer W held by the chuck table 55, and has a shaft portion 54a inserted in the chamber 53 via a bearing 56 so as to ascend and descend, and has a gas flow hole 57 formed therein being communicated with the gas feeding unit 51 and with an ejection portion 57a formed by using a porous member. The etching gas feeding means 54 is so constituted as to ascend and descend accompanying the ascending and descending motion of an ascending/descending unit 60 having a ball screw 59 driven by a motor 58 to rotate and having a nut screwed onto the ball screw 59.

The chuck table 55, on the other hand, has a shaft portion 55a rotatably inserted via a bearing 61, and a suction passage 63 communicated with a suction source 62 and a cooling passage 65 communicated with a cooling portion 64 are formed therein, the suction passage 63 being further communicated with a suction portion 63a in the upper surface.

The chamber 53 has an opening 66 in the side portion thereof to serve as a port for carrying the plate-like article to be etched in and out. A shutter 67 is arranged on the outer side of the opening 66 for opening and dosing the opening 66 upon being moved up and down. The shutter 67 moves up and down due to a piston 69, which moves up and down being driven by a cylinder 68.

At the lower part of the chamber 53, there is formed an exhaust port 71 communicated with a gas exhaust unit 70, and the used gas is exhausted through the exhaust port 71. A high-frequency power source 72 is connected to the etching gas feeding means 54 and to the chuck table 55 to feed a high-frequency voltage to plasmatize the etching gas.

Next, described below is the operation for forming the grooves G shown in FIG. 1(C) by etching the portions W1S corresponding to the streets by using the plasma etching device 5 shown in FIG. 5. The wafer W having the resist film R formed on the front surface W1 except the portions W1S corresponding to the streets as shown in FIG. 1(B), enters into the chamber 53 through the opening 66 in a state where the shutter 67 is descended to open the opening 66, and is held on the suction portion 63a in a state where the front surface W1 coated with the resist film R is exposed facing upward. The shutter 67 is returned back to the initial position to dose the opening 63, and the pressure in the interior is decreased by evacuation.

Next, the etching gas feeding means 54 is lowered and, in this state, the stable fluoride gas is fed as an etching gas into the gas flow hole 57 from the gas feeding unit 51. The etching gas is ejected from the ejection portion 57a in the lower surface of the etching gas feeding means 54, and a high-frequency voltage is applied across the etching gas feeding means 54 and the chuck table 55 from the high-frequency power source 72 to plasmatize the etching gas. Then, the portions not coated with the resist film R, i.e., the portions W1S corresponding to the streets only are etched on the front surface W1 of the wafer W due to the effect of etching with a plasma. Thereafter, as shown in FIG. 1(C), the etching is finished when the depth of the grooves G becomes equal to the finished thickness of the device D.

After finishing the grooves-forming step, the resist film R covering the front surface W1 of the wafer W is removed as shown FIG. 1(D) (resist film removing step). The resist film removing step may employ an ashing device or the plasma etching device 5 shown in FIG. 5.

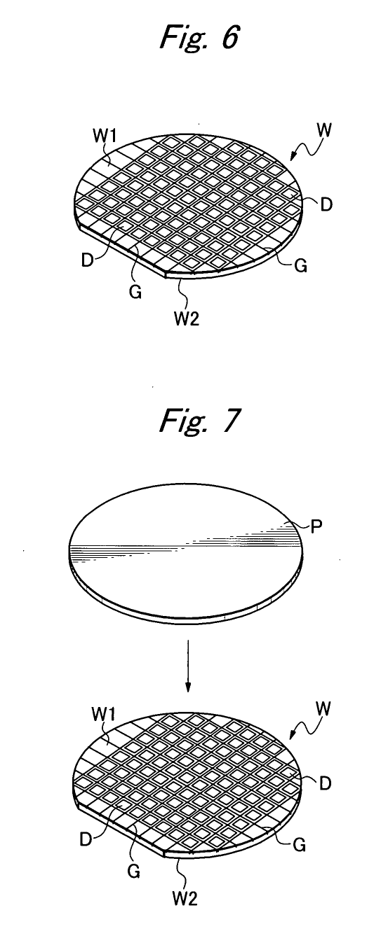

In the plasma etching device 5, the stable fluoride gas used in the grooves-forming step is exhausted into the gas exhaust unit 70 through the exhaust port 71 to establish a state where no stable fluoride gas exists in the chamber 53. Next, an O₂ gas is fed into the gas flow hole 57 from the gas feeding unit 51 and is ejected from the ejection portion 57a in the lower surface of the etching gas feeding means 54 while applying a high-frequency voltage across the etching gas feeding means 54 and the chuck table 55 from the high-frequency power source 72 to plasmatize the 02 gas. Then, the resist film R is oxidized, ashed and removed leaving only the wafer W forming the grooves G in the front surface W1 thereof as shown in FIGS. 1(D) and 6. The procedure may jump to the grinding step without carrying out the resist film removing step.

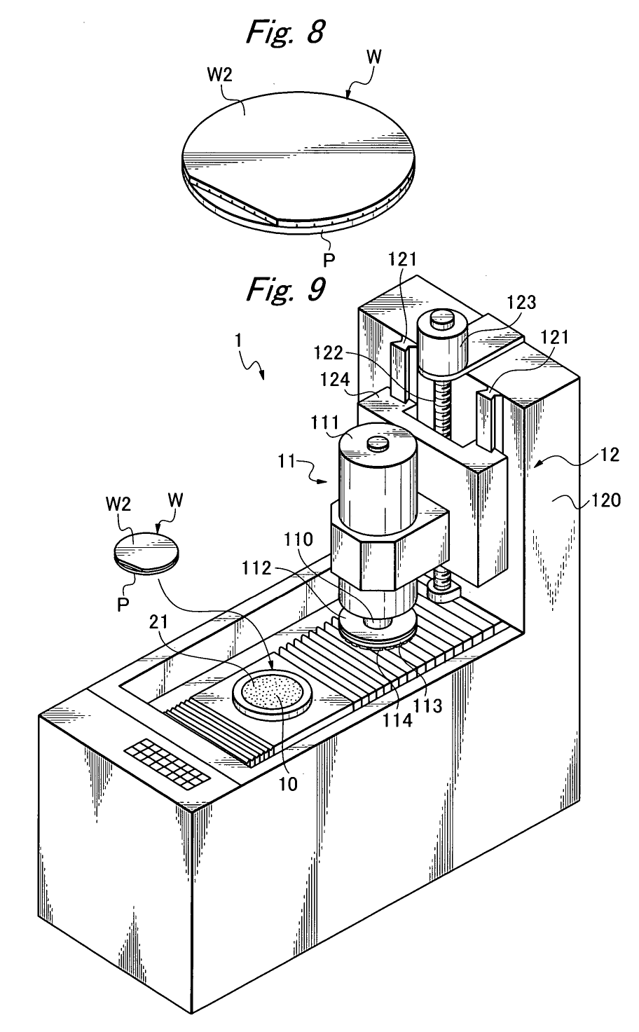

After the end of the resist film removing step, a protection member P is stuck to the front surface W1 of the wafer W as shown in FIGS. 1(E) and 7. The wafer W stuck the protection member P is turned inside out as shown in FIG. 8. Thereafter, the back surface W2 of the wafer W is ground so that the grooves G are exposed from the side of the back surface W2 (grinding step).

The grinding step may use a grinding device 1 shown in FIG. 9, for example. The grinding device 1 includes a chuck table 10 for holding the wafer, grinding means 11 for grinding the wafer held by the chuck table 10, and grind feed means 12 for bringing the grinding means 11 close to, or away from the chuck table 10.

The grinding means 11 is constituted by a spindle 110 having an axis in a perpendicular direction, a drive source 111 for rotating and driving the spindle 110, a grinding wheel 113 fixed to the lower end of the spindle 110 via a wheel mount 112, and a grindstone 114 fixed to the lower surface of the grinding wheel 113. The grindstone 114 rotates accompanying the rotation of the spindle 110 driven by the drive source 111.

The grind feed means 12 is constituted by a pair of guide rails 121 arranged on a wall portion 120 in a vertical direction, a ball screw 122 arranged in parallel with the guide rails 121, a pulse motor 123 coupled to an end of the ball screw 122, and a support portion 124 engaging with the guide rails 121 so as to slide and of which the nut in the interior thereof is screwed onto the ball screw 122. When the pulse motor 123 is driven and the ball screw 122 rotates, the support portion 124 ascends and descends being guided by the guide rails 121, and the grinding means 11 supported by the support portion 124 ascends and descends, too.

The chuck table 10 holds the protection member P, and the wafer W is placed in a state where its back surface W2 is exposed. As the chuck table 10 moves in a horizontal direction, the wafer W is positioned just under the grinding means 11. The wafer W positioned just under the grinding means 11 is rotated accompanying the rotation of the chuck table 10, and the grinding means 11 descends while the grindstone 114 is rotating and comes into contact with the back surface W2 of the wafer W to effect the grinding. As the grinding is continued, the grooves G appear from the back surface W2 as shown in FIG. 1(F), and the wafer W is divided into the individual devices D (grinding step). When the resist film removing step is not carried out, the resist film R is removed in the grinding step.

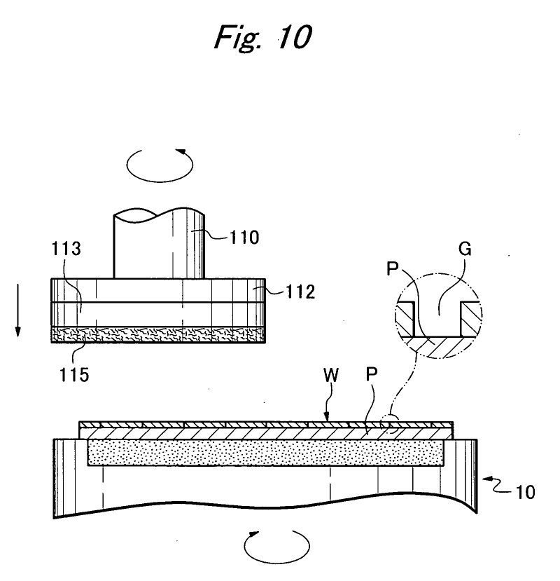

Upon carrying out the grinding step, there is formed a damage layer containing strain due to grinding the back surfaces of the devices D, whereby stress generates accounting for a drop of the die strength. In order to remove the damage layer, therefore, the stress-relieving step is carried out. Referring to FIG. 10, for example, the stress-relieving step is conducted by mounting a polishing pad 115 instead of the grindstone 114 on the grinding device 1 shown in FIG. 9, and polishing the back surface relying upon the same operation as that of the case of grinding. The damage layer can be removed even by dry etching or wet etching. In FIG. 10, portions other than the grindstone 115 are denoted by the same reference numerals as those for the grinding device 1 of FIG. 9.

In the grinding step, the grinding is finished while the thickness of the wafer W is still slightly greater than the finished thickness of the devices D. In the stress-relieving step, the damage layer is removed; i.e., the devices D after the stress-relieving step acquire the finished thickness.

As described above, the streets are all divided by the plasma etching and by the grinding of the back surface without requiring cutting by the cutting blade. Therefore, no chips come out on the devices and it permits neither the die strength nor the quality to be deteriorated. In the step of grinding, further, the streets are all divided simultaneously, which is very efficient, enabling the productivity to be improved. Further, the plasma etching is capable of conducting anisotropic etching to nearly vertically form the side surfaces of the devices D.

The steps of producing semiconductor devices can be roughly classified into pre-steps that are the steps of forming devices by forming circuits on the wafer, and post-steps that are the steps of machining the wafer on which the devices have been formed. The resist film coating step in the present invention is conducted by using an exposing device and a resist film-coating device, which are usually used in the pre-step. The grooves-forming step conducted after the resist film coating step, the resist film removing step, the grinding step and the stress-relieving step are conducted by using a plasma etching device, a grinding device and a stress-relieving device that are usually used in the post-step. Therefore, the devices that have heretofore been used in the pre-step and in the post-step can be used along the flow without the need of using in the post-step the devices that were so far used in the pre-step, simplifying the flow of the steps.

What is claimed is:

1. A method of dividing a wafer having a plurality of devices formed in front surface thereof being sectionalized by streets into individual devices, comprising:
a resist film coating step of coating the surface of the wafer with a resist film except the regions corresponding to the streets;
a grooves-forming step of plasmatizing a fluorine stabilizing gas and supplying it onto the surface of the wafer to form grooves of a depth equivalent to finishing thickness of the devices in the regions corresponding to said streets; and
a grinding step of sticking a protection member onto the front surface side, and grinding back surface of the wafer so that the grooves are exposed from the back surface side.

2. A method of dividing a wafer according to claim 1, wherein a resist film removing step is carried out for removing the resist film from the surface of the wafer after said grooves-forming step but before said grinding step.

3. A method of dividing a wafer according to claim 1, wherein a stress-relieving step is carried out for removing strain due to the grinding remaining in the back surface of said wafer after said grinding step.

4. A method of dividing a wafer according to claim 1, wherein said fluorine stabilizing gas is any one of SF₆, CF₄, C₂F₆, C₂F₄ or CHF₃.

5. A method of dividing a wafer according to claim 2, wherein in said resist film removing step, oxygen is plasmatized and is supplied onto said resist film to turn said resist film into ashes so as to be removed.
